(19) United States
(12) Patent Application Publication
(10) Pub. No.: US 2012/0155035 A1
(43) Pub. Date: Jun. 21, 2012

(54) DISPLAY DEVICE

(75) Inventors: Jeng-Hong CHEN, Taipei City (TW); Te-Sen CHIN, Taipei City (TW)

(73) Assignee: COMPAL ELECTRONICS, INC., Taipei City (TW)

(21) Appl. No.: 13/329,343

(22) Filed: Dec. 19, 2011

Related U.S. Application Data
(60) Provisional application No. 61/425,225, filed on Dec. 20, 2010.

(51) Int. Cl. H05K 7/00

(52) U.S. Cl. 361/728

(57) ABSTRACT

A display device includes a display module, an outer housing, a glass cover and a strength-enhanced member. The display module is installed within the outer housing, and the outer housing has a support portion. The glass cover is attached to the support portion. The strength-enhanced member is located within the outer housing, and the strength-enhanced member is disposed closer to a corresponding corner of the outer housing than a corresponding corner of the glass cover is.

### RELATED APPLICATIONS

This application claims priority to Provisional Application Ser. No. 61/425,225, filed Dec. 20, 2010, which is herein incorporated by reference.

### BACKGROUND

1. Field of Invention

The present invention relates to a display device. More particularly, the present invention relates to a display device with strength-enhanced corners.

2. Description of Related Art

A portable electronic device, such as a tablet computer or a smart phone, is one of the most popular products in the market. The portable electronic device is currently designed to be light, thin and compact, but its outer housing may not be robust enough to protect its weak components, such as a corner of a touch-control panel which is weak spot, from being damaged or broken.

A display module or a glass cover is a component with higher cost within a portable electronic device. When a corner of an electronic device collides with a hard object or falls on the ground, the glass cover and the display module are easily damaged or broken and need to be repaired with high cost. If the display module and glass cover are easily damaged or broken on their corners, the manufacturer will receives lots of complaints.

For the forgoing reasons, there is a need for reinforcing the outer housing of a display device.

### SUMMARY

It is therefore an objective of the present invention to provide a strength-enhanced outer housing of a display device.

In accordance with the foregoing and other objectives of the present invention, a display device includes a display module, an outer housing, a glass cover and a strength-enhanced member. The display module is installed within the outer housing, and the outer housing has a support portion. The glass cover is attached to the support portion. The strength-enhanced member is located within the outer housing, and the strength-enhanced member is disposed closer to a corresponding corner of the outer housing than a corresponding corner of the glass cover is.

According to another embodiment disclosed herein, the glass cover is located at an outer side of the support portion, and the strength-enhanced member is disposed at an inner side of the support portion.

According to another embodiment disclosed herein, the glass cover and the strength-enhanced member are located at an outer side of the support portion, and the strength-enhanced member is in contact with the glass cover.

According to another embodiment disclosed herein, the outer housing has a front bezel and a back cover, and the support portion is located at the front bezel.

According to another embodiment disclosed herein, the strength-enhanced member is embedded within the front bezel.

According to another embodiment disclosed herein, the strength-enhanced member is located at the front bezel and in contact with the glass cover.

According to another embodiment disclosed herein, the strength-enhanced member is located at the back cover.

According to another embodiment disclosed herein, the strength-enhanced member has an end secured to the front panel and an opposite end in contact with the back cover.

According to another embodiment disclosed herein, the back cover has a plurality of support ribs, and the strength-enhanced member has an end in contact with the support ribs.

According to another embodiment disclosed herein, the front bezel outer housing has a plurality of support ribs, and the strength-enhanced member has an end in contact with the support ribs.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates an exploded view of a display device according to a preferred embodiment of this invention;

FIG. 2 illustrates a top view of the display device in FIG. 1;

FIG. 3 illustrates a cross-sectional view (viewed along cross-sectional line A-A′ of FIG. 2) of a strength-enhanced corner according to a first embodiment of this invention;

FIG. 4 illustrates a cross-sectional view (viewed along cross-sectional line A-A′ of FIG. 2) of a strength-enhanced corner according to a second embodiment of this invention;

FIG. 5 illustrates a cross-sectional view (viewed along cross-sectional line A-A′ of FIG. 2) of a strength-enhanced corner according to a third embodiment of this invention;

FIG. 6 illustrates a cross-sectional view (viewed along cross-sectional line A-A′ of FIG. 2) of a strength-enhanced corner according to a fourth embodiment of this invention;

FIG. 7 illustrates a cross-sectional view (viewed along cross-sectional line A-A′ of FIG. 2) of a strength-enhanced corner according to a fifth embodiment of this invention;

FIG. 8 illustrates a cross-sectional view (viewed along cross-sectional line A-A′ of FIG. 2) of a strength-enhanced corner according to a sixth embodiment of this invention;

FIG. 9 illustrates a cross-sectional view (viewed along cross-sectional line A-A′ of FIG. 2) of a strength-enhanced corner according to a seventh embodiment of this invention;

FIG. 10 illustrates a perspective view of the strength-enhanced corner according to the fifth embodiment of this invention;

FIG. 11 illustrates a cross-sectional view (viewed along cross-sectional line B-B′ of FIG. 2) of a strength-enhanced corner according to the fifth embodiment of this invention;

FIG. 12 illustrates a perspective view of the strength-enhanced corner according to the seventh embodiment of this invention; and

FIG. 13 illustrates a cross-sectional view (viewed along cross-sectional line B-B′ of FIG. 2) of a strength-enhanced corner according to the seventh embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention provides a display device with its outer housing which is equipped with strength-enhanced corners to protect a glass cover or a display module from a crash impact. The strength-enhanced member protrudes out of an outmost rim of a corresponding corner of the glass cover. When a corner of the display device collides with a hard object or falls on the ground, the protruding-out portion of the strength-enhanced member receives a collision impact first so as to reduce the collision impact against a corresponding corner of the glass cover and the display module. In this invention, the glass cover could be a touch glass, wherein has a touch sensitive function.

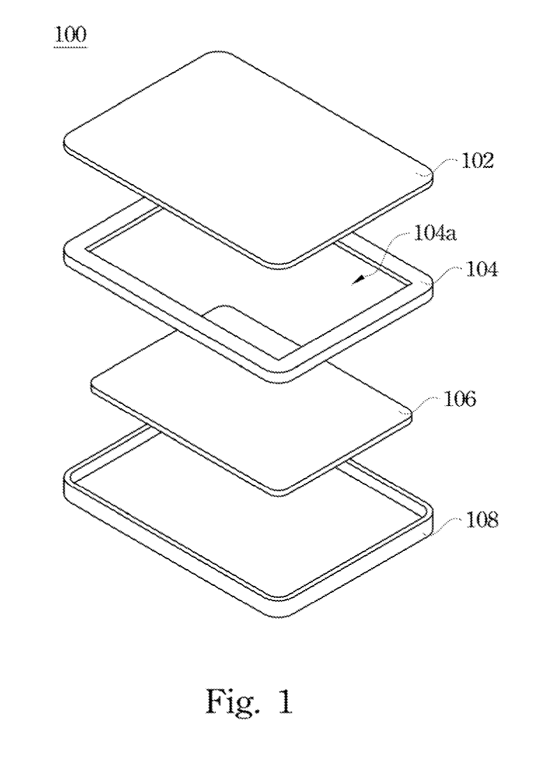

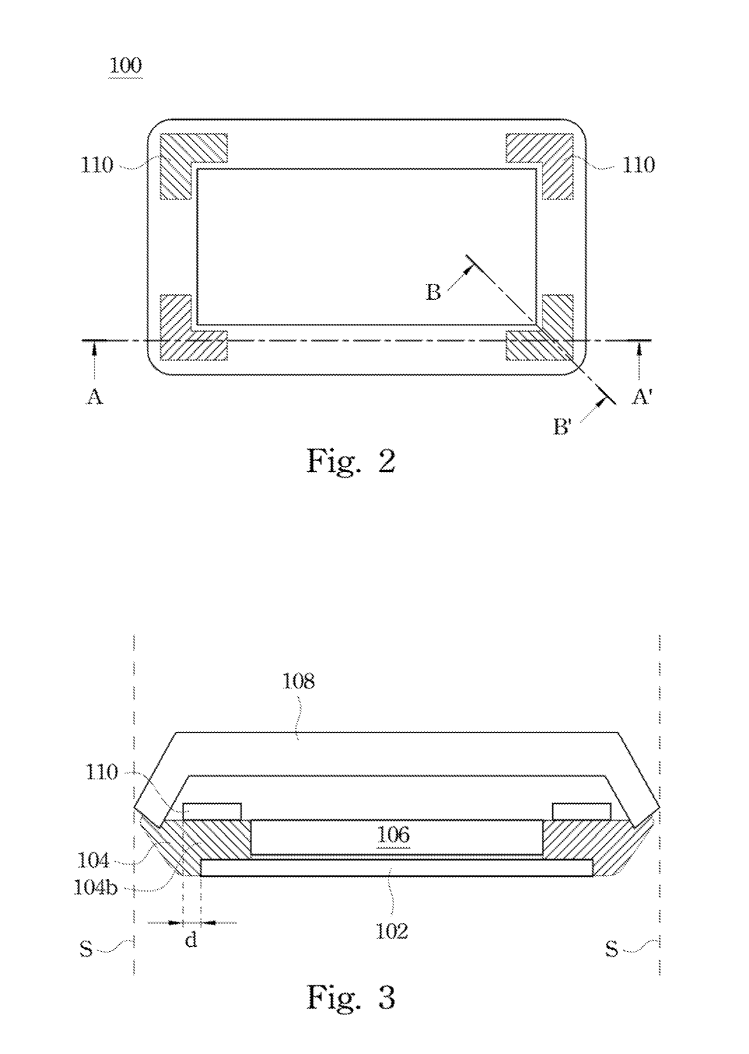

Referring to FIG. 1 and FIG. 2, FIG. 1 illustrates an exploded view of a display device according to a preferred embodiment of this invention, and FIG. 2 illustrates a top view of the display device in FIG. 1. The display device 100 basically includes a glass cover 102, a front bezel 104, a display module 106 and a back cover 108. The front bezel 104 and the back cover 108 collectively form a complete outer housing to enclose the display module 106. The front bezel 104 has a display window 104a used for exposing the display module 106 such that the display module 106 can output images through the display window 104a. The glass cover 102 is used to cover the display window 104a. In order to strengthen corners of the outer housing, a strength-enhanced member 110 can be embedded into at least one corner of the outer housing (referring to FIG. 2) to reinforce corners against crash impacts. In this embodiment, the strength-enhanced member 110 can be an L-shape metallic member or reinforced plastic members of other shapes, but the strength-enhanced member 110 is not limited to those materials or shapes. In addition, a mechanical strength of the strength-enhanced member 110 is better than that of the front bezel 104 or the back cover 108.

FIG. 3 illustrates a cross-sectional view (viewed along cross-sectional line A-A′ of FIG. 2) of a strength-enhanced corner according to a first embodiment of this invention. The glass cover 102 is attached to an outer side of the support portion 104b , of the front bezel 104. In the first embodiment, the strength-enhanced member 110 is attached at an inner side of the support portion 104b of the front bezel 104, and the strength-enhanced member 110 protrudes out a distance d from a corresponding corner of the glass cover 102. That is, the strength-enhanced member 110 is disposed closer to a corresponding corner of the outer housing than a corresponding corner of the glass cover 102 is. It is noted that the dash-line S indicates an outmost rim of the corresponding corner of the outer housing. In this embodiment, the distance d can be 2 mm, but the distance d can be varied according to a design of the outer housing. When the display device collides with a hard object or falls on the ground, the protruding-out portion of the strength-enhanced member 110 receives a collision impact first so as to reduce the collision impact against a corresponding corner of the glass cover 102 and the display module 106. The strength-enhanced member 110 can be adhered to the front bezel 104 or fastened to the front bezel 104 with bolts.

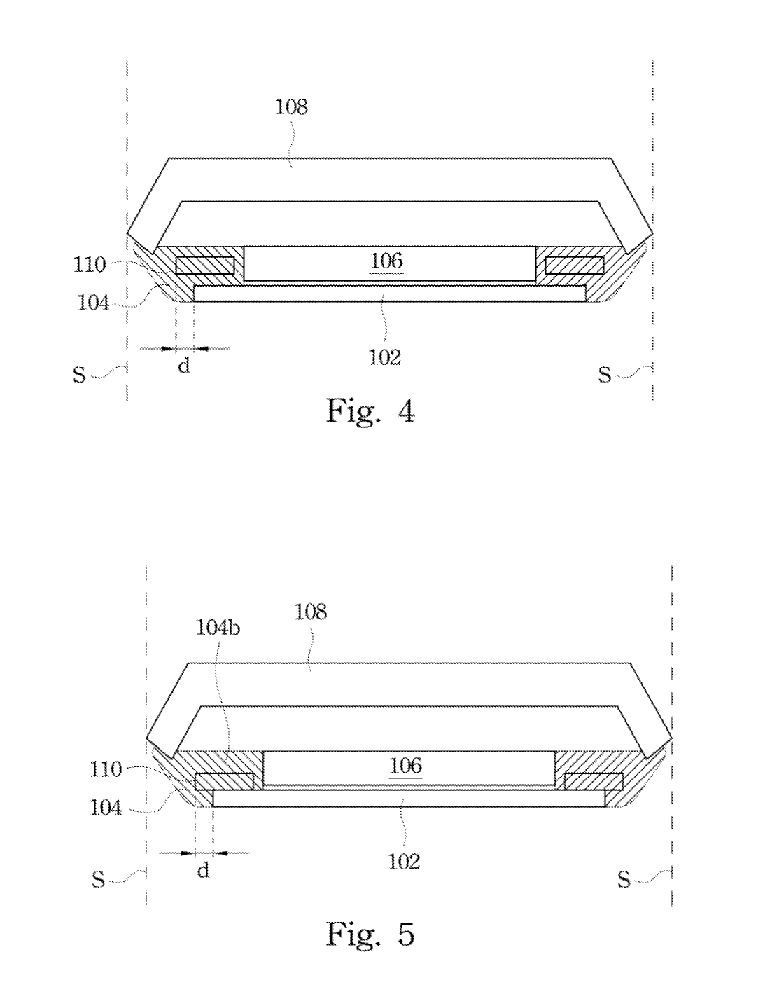

FIG. 4 illustrates a cross-sectional view (viewed along cross-sectional line A-A′ of FIG. 2) of a strength-enhanced corner according to a second embodiment of this invention. In the second embodiment, the strength-enhanced member 110 is embedded into the front bezel 104 when the front bezel 104 is manufactured by a injection process, and the strength-enhanced member 110 protrudes out a distance d from a corresponding corner of the glass cover 102. That is, the strength-enhanced member 110 is disposed closer to a corresponding corner of the outer housing than a corresponding corner of the glass cover 102 is. It is noted that the dash-line S indicates an outmost rim of the corresponding corner of the outer housing. In this embodiment, the distance d can be 2 mm, but the distance d can be varied according to a design of the outer housing. When the display device collides with a hard object or falls on the ground, the protruding-out portion of the strength-enhanced member 110 receives a collision impact first so as to reduce the collision impact against a corresponding corner of the glass cover 102 and the display module 106.

FIG. 5 illustrates a cross-sectional view (viewed along cross-sectional line A-A′ of FIG. 2) of a strength-enhanced corner according to a third embodiment of this invention. In the third embodiment, the strength-enhanced member 110 and the glass cover 102 are both disposed at an outer side of the support portion 104b of the front bezel 104, and the strength-enhanced member 110 are in contact with an inner surface of the glass cover 102 partially. The strength-enhanced member 110 protrudes out a distance d from a corresponding corner of the glass cover 102, that is, the strength-enhanced member 110 is disposed closer to a corresponding corner of the outer housing than a corresponding corner of the glass cover 102 is. It is noted that the dash-line S indicates an outmost rim of the corresponding corner of the outer housing. In this embodiment, the distance d can be 2 mm, but the distance d can be varied according to a design of the outer housing. When the display device collides with a hard object, the protruding-out portion of the strength-enhanced member 110 receive a collision impact first so as to reduce the collision impact against a corresponding corner of the glass cover 102 and the display module 106.

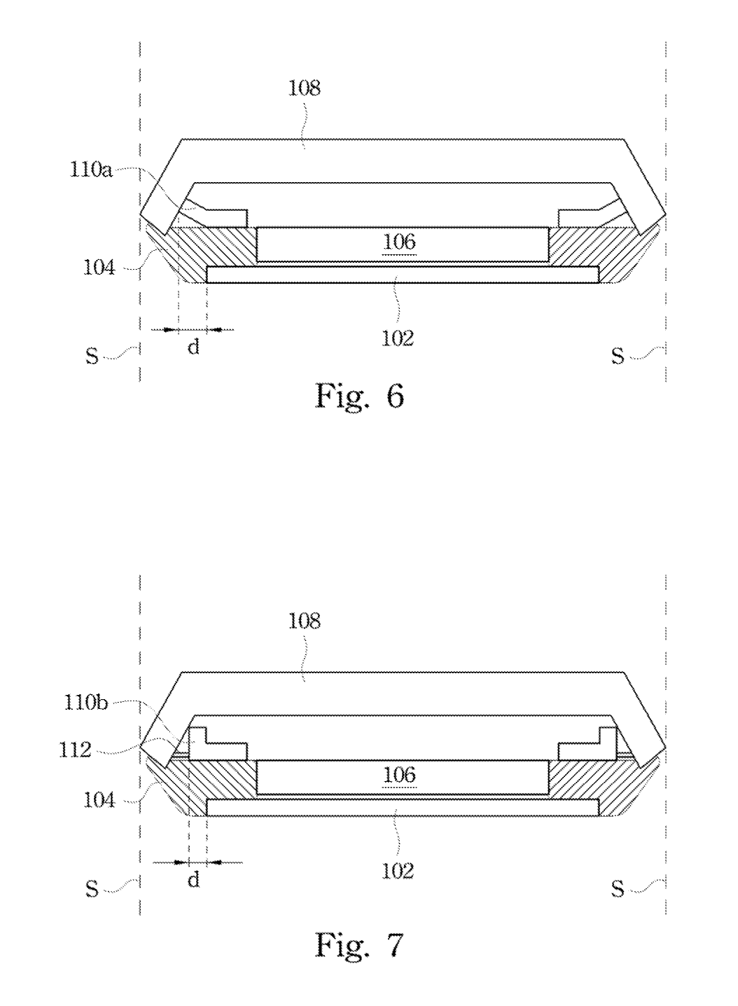

FIG. 6 illustrates a cross-sectional view (viewed along cross-sectional line A-A′ of FIG. 2) of a strength-enhanced corner according to a fourth embodiment of this invention. In the fourth embodiment, the strength-enhanced member 110a has one end attached to an inner side of the front bezel 104 and an opposite end in contact with an inner surface of the hack cover 108. The strength-enhanced member 110a protrudes out a distance d from a corresponding corner of the glass cover 102. That is, the strength-enhanced member 110a is disposed closer to a corresponding corner of the outer housing than a corresponding corner of the glass cover 102 is. It is noted that the dash-line S indicates an outmost rim of the corresponding corner of the outer housing. In this embodiment, the distance d can be 2 mm, but the distance d can be varied according to a design of the outer housing. When the display device collides with a hard object or falls on the ground, the protruding-out portion of the strength-enhanced member 110 receives a collision impact first so as to reduce the collision impact against a corresponding corner of the glass cover 102 and the display module 106. The strength-enhanced member 110 can be adhered to the front bezel 104 or fastened to the front bezel 104 with bolts.

FIG. 7 illustrates a cross-sectional view (viewed along cross-sectional line A-A′ of FIG. 2) of a strength-enhanced corner according to a fifth embodiment of this invention. In the fifth embodiment, the strength-enhanced member 110b has one end attached to an inner side of the front bezel 104 and an opposite end in contact with several support ribs 112 of the front bezel 104. The strength-enhanced member 110b protrudes out a distance d from a corresponding corner of the glass cover 102. That is, the strength-enhanced member 110b is disposed closer to a corresponding corner of the outer housing than a corresponding corner of the glass cover 102 is. It is noted that the dash-line S indicates an outmost rim of the corresponding corner of the outer housing. In this embodiment, the distance d can be 2 mm, but the distance d can be varied according to a design of the outer housing. When the display device collides with a hard object or falls on the ground, the protruding-out portion of the strength-enhanced member 110b receives a collision impact first so as to reduce the collision impact against a corresponding corner of the glass cover 102 and the display module 106. The strength-enhanced member 110b can be adhered to the front bezel 104 or fastened to the front bezel 104 with bolts.

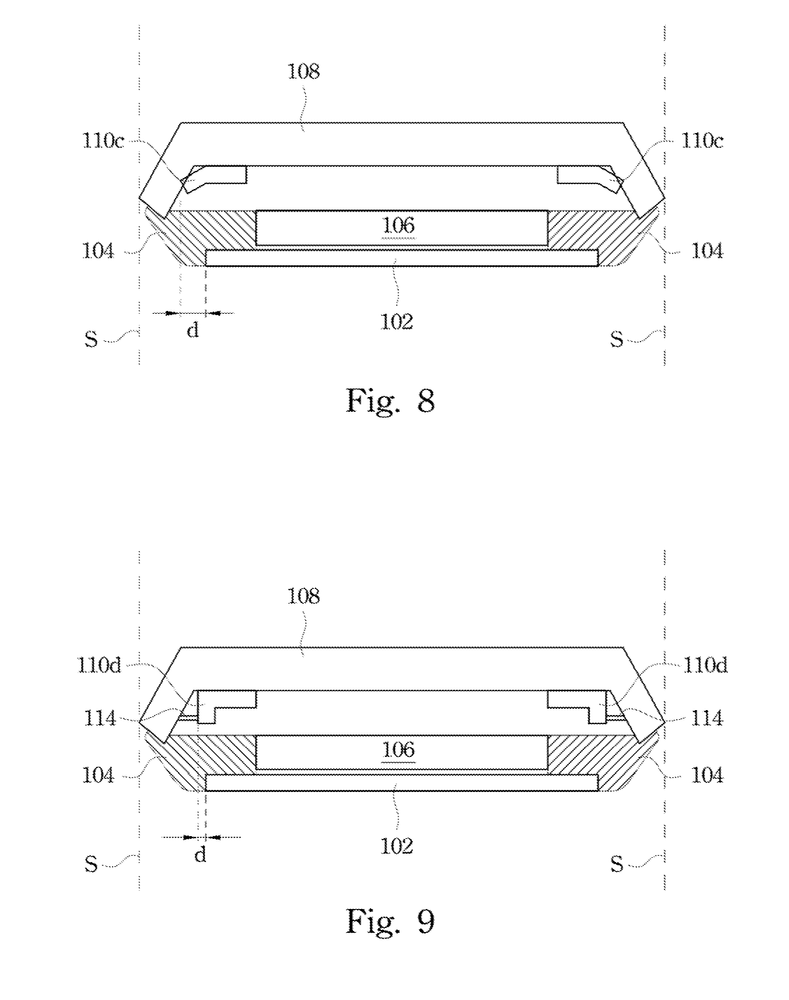

FIG. 8 illustrates a cross-sectional view (viewed along cross-sectional line A-A′ of FIG. 2) of a strength-enhanced corner according to a sixth embodiment of this invention. In the sixth embodiment, the strength-enhanced member 110c is attached to an inner surface of the back cover 108, and the strength-enhanced member 110c protrudes out a distance d from a corresponding corner of the glass cover 102. That is, the strength-enhanced member 110c is disposed closer to a corresponding corner of the outer housing than a corresponding corner of the glass cover 102 is. It is noted that the dash-line S indicates an outmost rim of the corresponding corner of the outer housing. In this embodiment, the distance d can be 2 mm, but the distance d can be varied according to a design of the outer housing. When the display device collides with a hard object or falls on the ground, the protruding-out portion of the strength-enhanced member 110c receives a collision impact first so as to reduce the collision impact against a corresponding corner of the glass cover 102 and the display module 106.

The strength-enhanced member 110c can be adhered to the back cover 108 or fastened to the back cover 108 with bolts.

FIG. 9 illustrates a cross-sectional view (viewed along cross-sectional line A-A′ of FIG. 2) of a strength-enhanced corner according to a seventh embodiment of this invention. In the seventh embodiment, the strength-enhanced member 110d is attached to an inner surface of the back cover 108 and has an end in contact with several support ribs 114 at a corresponding corner of the back cover 108, and the strength-enhanced member 110d protrudes out a distance d from a corresponding corner of the glass cover 102. That is, the strength-enhanced member 110d is disposed Closer to a corresponding corner of the outer housing than a corresponding corner of the glass cover 102 is. It is noted that the dash-line S indicates an outmost rim of the corresponding corner of the outer housing. In this embodiment, the distance d can be 2 mm, but the distance d can be varied according to a design of the outer housing. When the display device collides with a hard object or falls on the ground, the protruding-out portion of the strength-enhanced member 110d receives a collision impact first so as to reduce the collision impact against a corresponding corner of the glass cover 102 and the display module 106. The strength-enhanced member 110d can be adhered to the back cover 108 or fastened to the back cover 108 with bolts.

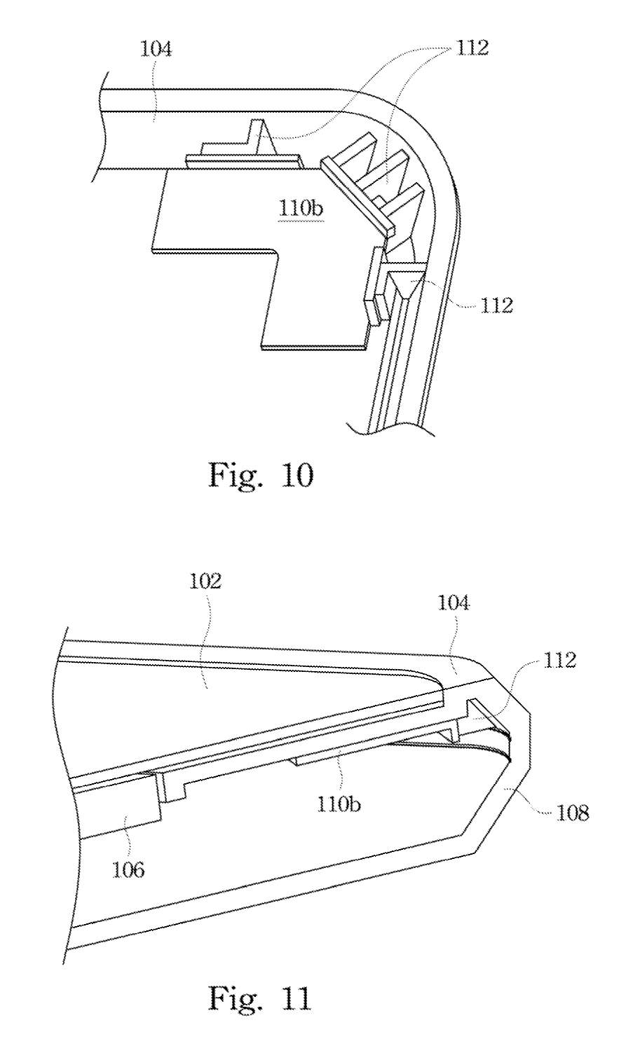

Referring both to FIG. 10 and FIG. 11, FIG. 10 illustrates a perspective view of the strength-enhanced corner according to the fifth embodiment of this invention, and FIG. 11 illustrates a cross-sectional view (viewed along cross-sectional line B-B′ of FIG. 2) of a strength-enhanced corner according to the fifth embodiment of this invention. In the fifth embodiment, there are several support ribs 112 at the corners of the front bezel 104 to further reinforce a mechanical strength of the corresponding corner. The strength-enhanced member 110b is attached to an inner surface of the front bezel 104 and has its three end surfaces in contact with respective support ribs 112 to further reinforce a mechanical strength of the corresponding corner.

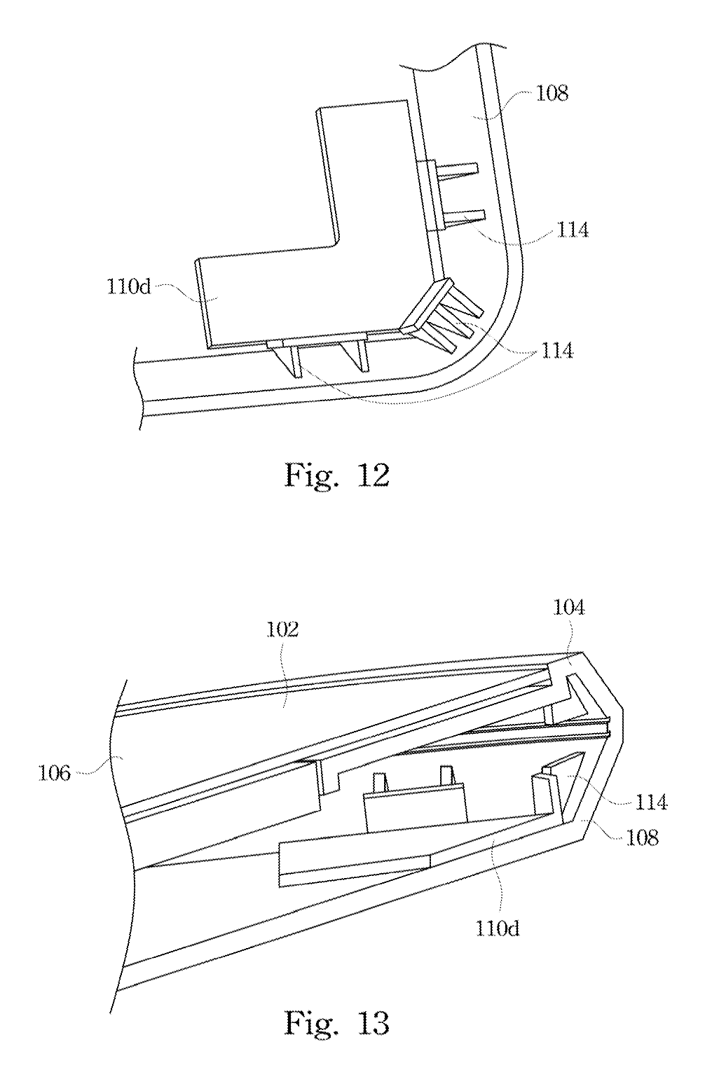

Referring to both FIG. 12 and FIG. 13, FIG. 12 illustrates a perspective view of the strength-enhanced corner according to the seventh embodiment of this invention, and FIG. 13 illustrates a cross-sectional view (viewed along cross-sectional line B-B′ of FIG. 2) of a strength-enhanced corner according to the seventh embodiment of this invention. In the seventh embodiment, there are several support ribs 114 at the corners of the back cover 108 to further reinforce a mechanical strength of the corresponding corner. The strength-enhanced member 110d is attached to an inner surface of the back cover 108 and has its three end surfaces in contact with respective support ribs 114 to further reinforce a mechanical strength of the corresponding corner.

According to the above-discussed embodiments, the display device disclosed herein has its outer housing's corners equipped with the strength-enhanced members. The strength-enhanced member protrudes out of a corresponding corner of the glass cover. When a corner of the display device collides with a hard object, the protruding-out portion of the strength-enhanced member receives a collision impact first so as to reduce the collision impact against a corresponding corner of the glass cover and the display module. In addition, the strength-enhanced member can be located at the corners of the front bezel or the back cover, and can be in contact with the support ribs at the corners of the front bezel or the back cover to further reinforce a mechanical strength of the corresponding corner.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A display device comprising:
a display module;
an outer housing, wherein the display module is disposed within the outer housing, and the outer housing has a support portion;
a glass cover attached to the support portion; and
a strength-enhanced member disposed within the outer housing, wherein the strength-enhanced member is disposed closer to an outmost rim of a corresponding corner of the outer housing than a corresponding corner of the glass cover is.

2. The display device of claim 1, wherein the glass cover is disposed at an outer side of the support portion, and the strength-enhanced member is disposed at an inner side of the support portion.

3. The display device of claim 1, wherein the glass cover and the strength-enhanced member are disposed at an outer side of the support portion, and the strength-enhanced member is in contact with the glass cover.

4. The display device of claim 1, wherein the outer housing has a front bezel and a back cover, and the support portion is disposed at the front bezel.

5. The display device of claim 4, wherein the strength-enhanced member is embedded within the front bezel.

6. The display device of claim 4, wherein the strength-enhanced member is disposed at the front bezel and in contact with the glass cover.

7. The display device of claim 4, wherein the strength-enhanced member is disposed at the back cover.

8. The display device of claim 4, wherein the strength-enhanced member has an end secured to the front panel and an opposite end in contact with the back cover.

9. The display device of claim 4, wherein the back cover has a plurality of support ribs, and the strength-enhanced member has an end in contact with the support ribs.

10. The display device of claim 4, wherein the front bezel outer housing has a plurality of support ribs, and the strength-enhanced member, has an end in contact with the support ribs.
